(19) United States
(12) Patent Application Publication
(10) Pub. No.: US 2024/0203817 A1
(43) Pub. Date: Jun. 20, 2024

(54) SEMICONDUCTOR APPARATUS, AND MANUFACTURING METHOD THEREFOR

(71) Applicant: ROHM CO., LTD., Kyoto-shi (JP)

(72) Inventor: Natsuya YOSHIDA, Kyoto-shi (JP)

(21) Appl. No.: 18/591,744

(22) Filed: Feb. 29, 2024

Related U.S. Application Data
(63) Continuation of application No. PCT/JP2022/026677, filed on Jul. 5, 2022.

(30) Foreign Application Priority Data
Sep. 2, 2021 (JP) 2021-143182

(51) Int. Cl. H01L 23/367; H01L 21/56; H01L 23/31; H01L 23/373; H01L 23/42; H01L 23/467; H01L 23/473

(52) U.S. Cl. CPC H01L 23/367; H01L 21/56; H01L 23/3107; H01L 23/3736; H01L 23/42; H01L 23/467; H01L 23/473

(57) ABSTRACT

A semiconductor apparatus includes a semiconductor chip, a supporting body that has an upper surface and a lower surface and with which the semiconductor chip is fixed to the upper surface, a sealing resin that is arranged to seal the semiconductor chip and the supporting body, and a heat sink that is bonded to the lower surface of the supporting body, a recess portion is formed in an upper surface of the heat sink, the lower surface of the supporting body is bonded to a bottom surface of the recess portion via a bonding structure, and the sealing resin infiltrates a gap between at least the bonding structure among the supporting body and the bonding structure and a side surface of the recess portion.

### CROSS REFERENCE TO RELATED APPLICATIONS

The present application is a continuation application of PCT Application No. PCT/JP2022/026677, filed on Jul. 5, 2022, which corresponds to Japanese Patent Application No. 2021-143182 filed on Sep. 2, 2021 with the Japan Patent Office, and the entire disclosure of this application is incorporated herein by reference.

### TECHNICAL FIELD

The present disclosure relates to a semiconductor apparatus and a manufacturing method therefor.

### BACKGROUND ART

A semiconductor apparatus including a semiconductor chip, a supporting body with which the semiconductor chip is fixed to an upper surface, a sealing resin arranged to seal the semiconductor chip and the supporting body, and a heat sink bonded to a lower surface of the supporting body has been developed (see, for example, WO Publication No. 2018/207856).

### BRIEF DESCRIPTION OF DRAWINGS

FIG. 1 is an illustrative sectional view for describing the arrangement of a semiconductor apparatus according to a first preferred embodiment of the present disclosure.

FIG. 2 is an enlarged sectional view of a portion A of FIG. 1.

FIG. 3A is a sectional view showing an example of a manufacturing process of the semiconductor apparatus of FIG. 1 and is a sectional view corresponding to the section plane of FIG. 1.

FIG. 3B is a sectional view showing a step subsequent to that of FIG. 3A.

FIG. 3C is a sectional view showing a step subsequent to that of FIG. 3B.

FIG. 3D is a sectional view showing a step subsequent to that of FIG. 3C.

FIG. 4 is an enlarged sectional view showing a modification example of an insulating substrate.

FIG. 5A is an enlarged sectional view showing a modification example of a heat sink.

FIG. 5B is an enlarged sectional view showing another modification example of the heat sink.

FIG. 6 is an enlarged sectional view showing a modification example of a shape of a side surface of a recess portion.

FIG. 7 is an enlarged sectional view showing a modification example of a depth of the recess portion.

FIG. 8 is an illustrative sectional view for describing the arrangement of a semiconductor apparatus according to a second preferred embodiment of the present disclosure.

FIG. 9 is an enlarged sectional view of a portion A of FIG. 8.

FIG. 10 is an illustrative sectional view for describing the arrangement of a semiconductor apparatus according to a third preferred embodiment of the present disclosure.

FIG. 11 is an enlarged sectional view of a portion A of FIG. 10.

### DESCRIPTION OF EMBODIMENTS

A preferred embodiment of the present disclosure provides a semiconductor apparatus including a semiconductor chip, a supporting body that has an upper surface and a lower surface and with which the semiconductor chip is fixed to the upper surface, a sealing resin that is arranged to seal the semiconductor chip and the supporting body, and a heat sink that is bonded to the lower surface of the supporting body and where a recess portion is formed in an upper surface of the heat sink, the lower surface of the supporting body is bonded to a bottom surface of the recess portion via a bonding structure, and the sealing resin infiltrates a gap between at least the bonding structure among the supporting body and the bonding structure and a side surface of the recess portion.

With this arrangement, aging degradation of a bonding interface between the supporting body and the heat sink can be suppressed.

In the preferred embodiment of the present disclosure, the side surface of the recess portion is formed to a curved surface shape or an inclined surface shape with which an area of a lateral cross section of the recess portion increases gradually from the bottom surface of the recess portion toward an opening of the recess portion at the upper surface of the heat sink.

In the preferred embodiment of the present disclosure, the bonding structure includes a solid phase diffusion bonding sheet.

In the preferred embodiment of the present disclosure, the solid phase diffusion bonding sheet is constituted of an Al layer, a first laminated film with which an Ni layer and an Ag layer are formed in that order on a lower surface of the Al layer, and a second laminated film with which an Ni layer and an Ag layer are formed in that order on an upper surface of the Al layer.

In the preferred embodiment of the present disclosure, the bonding structure includes a first solid phase diffusion bonding sheet, a second solid phase diffusion bonding sheet that is disposed at an upper side of the first solid phase diffusion bonding sheet, and a stress buffer layer that is provided between the first solid phase diffusion bonding sheet and the second solid phase diffusion bonding sheet.

In the preferred embodiment of the present disclosure, each solid phase diffusion bonding sheet is constituted of an Al layer, a first laminated film with which an Ni layer and an Ag layer are formed in that order on a lower surface of the Al layer, and a second laminated film with which an Ni layer and an Ag layer are formed in that order on an upper surface of the Al layer.

In the preferred embodiment of the present disclosure, the stress buffer layer is constituted of a CuMo layer.

In the preferred embodiment of the present disclosure, the bonding structure includes sintered silver.

In the preferred embodiment of the present disclosure, the bonding structure includes solder.

In the preferred embodiment of the present disclosure, the supporting body includes an insulating substrate and a metal substrate disposed on the insulating substrate and the semiconductor chip is fixed to a surface of the metal substrate at an opposite side to the insulating substrate.

In the preferred embodiment of the present disclosure, the supporting body is constituted of an insulating substrate.

In the preferred embodiment of the present disclosure, the heat sink is a water cooler.

In the preferred embodiment of the present disclosure, the heat sink is an air cooler.

In the preferred embodiment of the present disclosure, the heat sink is constituted of a Cu block.

A preferred embodiment of the present disclosure provides a method for manufacturing a semiconductor apparatus that includes a semiconductor chip, a supporting body having an upper surface and a lower surface and with which the semiconductor chip is fixed to the upper surface, a heat sink bonded to the lower surface of the supporting body, and a sealing resin sealing the semiconductor chip and the supporting body, the method for manufacturing the semiconductor apparatus including a bonding step of bonding the semiconductor chip, the supporting body, and the heat sink and a sealing step of sealing the semiconductor chip and the supporting body by the sealing resin.

With this method for manufacturing, the semiconductor apparatus with which aging degradation of a bonding interface between the supporting body and the heat sink can be suppressed can be manufactured.

In the bonding step, at least bonding of the supporting body and the heat sink among bonding of the semiconductor chip and the supporting body and the bonding of the supporting body and the heat sink is performed by solid phase diffusion bonding.

In the following, preferred embodiments of the present disclosure shall be described in detail with reference to the attached drawings.

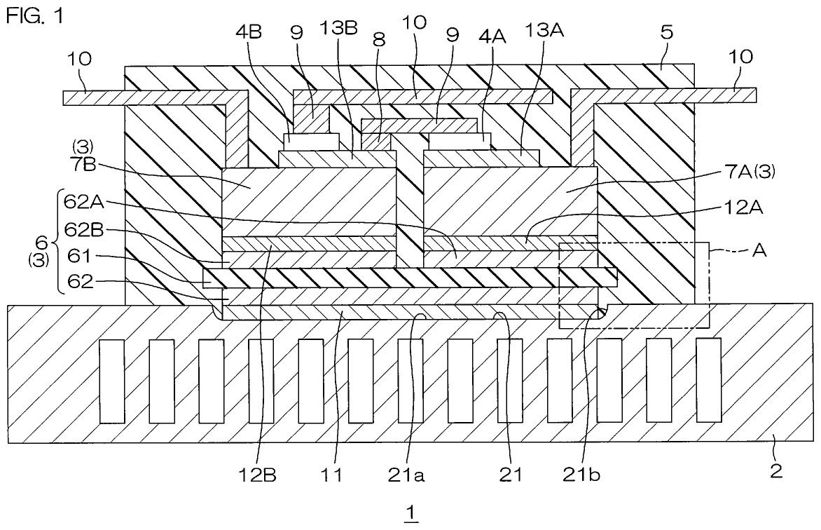

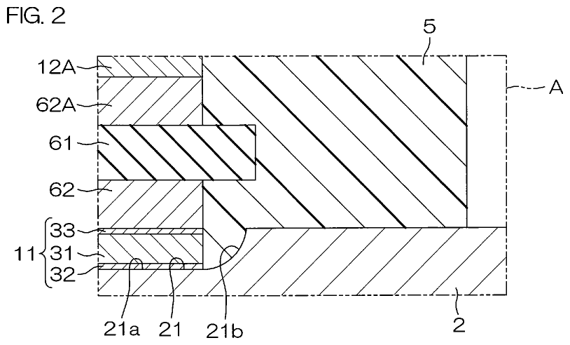

FIG. 1 is an illustrative sectional view for describing the arrangement of a semiconductor apparatus according to a first preferred embodiment of the present disclosure. FIG. 2 is an enlarged sectional view of a portion A of FIG. 1. For convenience of description, the left side of the sheet of FIG. 1 shall be referred to as the “left” and the right side of the sheet of FIG. 1 shall be referred to as the “right.”

A semiconductor apparatus 1 is a power module. The semiconductor apparatus 1 includes a heat sink 2, a supporting body 3 that is bonded to an upper surface of the heat sink 2, semiconductor chips 4A and 4B that are fixed to an upper surface of the supporting body 3, and a sealing resin 5 that seals the semiconductor chips 4A and 4B and the supporting body 3. A major portion (module portion) of the semiconductor apparatus 1 excluding the heat sink 2 has a rectangular parallelepiped shape.

In this preferred embodiment, the heat sink 2 is a water cooler with which a cooling liquid such as cooling water, oil, etc., is made to flow inside holes formed inside the heat sink 2.

The supporting body 3 includes an insulating substrate 6 that is bonded to the upper surface of the heat sink 2 via a first bonding structure 11 and a right and left pair of metal substrates 7A and 7B that are bonded on the insulating substrate 6 via a right and left pair of second bonding structures 12A and 12B.

In this preferred embodiment, the insulating substrate 6 is prepared from a DBC (direct bonded copper) substrate and is constituted of a ceramic plate 61, a copper foil 62 that is formed on a lower surface of the ceramic plate 61, and a right and left pair of copper foils 62A and 62B that are disposed at an interval on an upper surface of the ceramic plate 61.

The metal substrate 7A at the right side is bonded to an upper surface of the copper foil 62A at the right side via the second bonding structure 12A at the right side. The metal substrate 7B at the left side is bonded to an upper surface of the copper foil 62B at the left side via the second bonding structure 12B at the left side. In this preferred embodiment, the metal substrates 7A and 7B are constituted of copper substrates.

The semiconductor chip 4A is bonded on the metal substrate 7A at the right side via a third bonding structure 13A (the third bonding structure 13A at the right side). The semiconductor chip 4B and a spacer 8 to be described below is bonded on the metal substrate 7B at the left side via a third bonding structure 13B (the third bonding structure 13B at the left side). The semiconductor chip 4A at the right side is a switching element for a high side and the semiconductor chip 4B at the left side is a switching element for a low side.

The first bonding structure 11, the second bonding structures 12A and 12B, and the third bonding structures 13A and 13B each include a solid phase diffusion bonding sheet. That is, in this preferred embodiment, the insulating substrate 6 and the heat sink 2 are bonded by solid phase diffusion bonding. Also, the insulating substrate 6 and the metal substrates 7A and 7B are bonded by solid phase diffusion bonding. Also, the semiconductor chip 4A is bonded to the metal substrate 7A by solid phase diffusion bonding. Also, the semiconductor chip 4B and the spacer 8 are bonded to the metal substrate 7B by solid phase diffusion bonding.

In this preferred embodiment, each solid phase diffusion bonding sheet is constituted of an Al preformed sheet as shown in FIG. 2. The Al preformed sheet is constituted of an Al layer 31, a first laminated film 32 that is formed on a lower surface of the Al layer 31, and a second laminated film 33 that is formed on an upper surface of the Al layer. The first laminated film 32 is constituted of an Ni layer formed on the lower surface of the Al layer 31 and an Ag layer formed on a lower surface of the Ni layer. The second laminated film 33 is constituted of an Ni layer formed on the upper surface of the Al layer 31 and an Ag layer formed on an upper surface of the Ni layer.

The semiconductor apparatus 1 includes the spacer 8 disposed on the metal substrate 7B at the left side, wirings 9 connected to the spacer 8 and the semiconductor chips 4A and 4B, and terminals 10. Although the terminals 10 include a positive power supply terminal, a negative power supply terminal, an output terminal, a gate terminal, etc., just a portion thereof appears in FIG. 1.

A recess portion 21 having an outer peripheral edge (opening edge) such that surrounds a lower surface of the supporting body 3 in plan view is formed in the upper surface of the heat sink 2. The lower surface of the supporting body 3 (lower surface of the insulating substrate 6) is bonded via the first bonding structure 11 to a bottom surface 21a of the recess portion 21. In this preferred embodiment, substantially the entire first bonding structure 11 is disposed inside the recess portion 21. That is, a side surface 21b of the recess portion 21 is disposed such as to surround an outer peripheral surface of the first bonding structure 11.

In this preferred embodiment, the side surface 21b of the recess portion 21 is formed to a curved surface shape with which an area of a lateral cross section of the recess portion 21 increases gradually from the bottom surface of the recess portion 21 toward an opening of the recess portion 21 at the upper surface of the heat sink 2. As shall be described below, in this preferred embodiment, the recess portion 21 is formed in a process of manufacturing the semiconductor apparatus 1, more specifically, when bonding the heat sink 2, the insulating substrate 6, the metal substrates 7A and 7B, the semiconductor chips 4A and 4B, and spacer 8 altogether.

The sealing resin 5 has a quadrilateral shape slightly larger than the supporting body 3 in plan view and is formed such as to cover a portion of the terminals 10, the wirings 9, the supporting body 3, and a region of the heat sink 2 upper surface in a vicinity of the supporting body 3. A portion of the sealing resin 5 infiltrates an entirety of a space portion between portions of the first bonding structure 11 and the supporting body 3 that are disposed inside the recess portion 21 (in this preferred embodiment, substantially the entire first bonding structure 11) and the side surface 21b of the recess portion 21. Here, portions of the terminals 10 that project from the sealing resin 5 become external wiring connection portions arranged to connect the terminals 10 to external wirings. The sealing resin 5 is constituted, for example, of an epoxy resin.

With the semiconductor apparatus 1 of this preferred embodiment, the recess portion 21 is formed in the heat sink 2 upper surface and the lower surface of the supporting body 3 is bonded to the bottom surface 21a of the recess portion 21 via the first bonding structure 11. And a portion of the sealing resin 5 infiltrates the entirety of the space portion between the portions of the first bonding structure 11 and the supporting body 3 that are disposed inside the recess portion 21 (in this preferred embodiment, substantially the entire first bonding structure 11) and the side surface 21b of the recess portion 21. A so-called anchor effect acts thereby and the sealing resin 5 is made unlikely to peel off from the heat sink 2. A bonding strength of the heat sink 2 and the supporting body 3 (insulating substrate 6) can thereby be increased. Aging degradation of a bonding interface between the supporting body 3 and the heat sink 2 can thereby be suppressed.

Also, with the semiconductor apparatus 1 of this preferred embodiment, since the heat sink 2 and the supporting body 3 (insulating substrate 6) are bonded by solid phase diffusion bonding, aging degradation of the bonding interface therebetween can be suppressed in comparison to a case where these are solder bonded or silver sinter bonded.

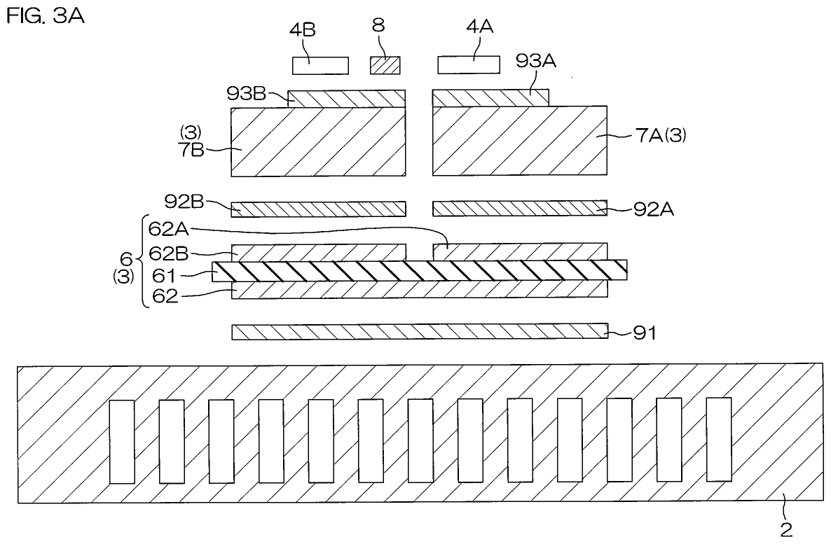

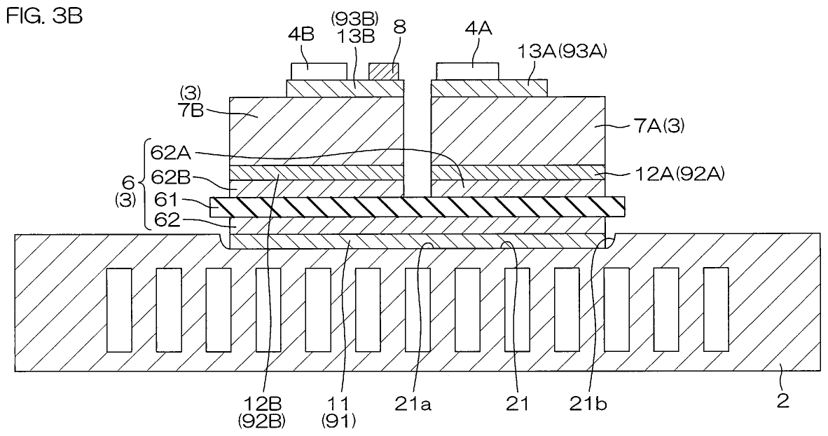

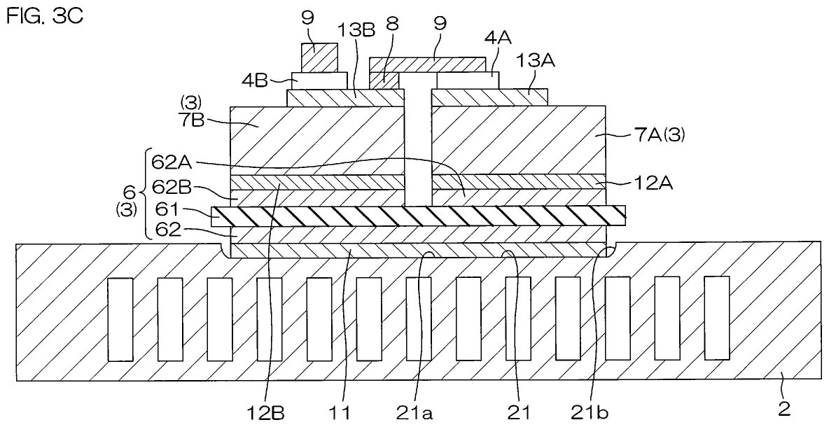

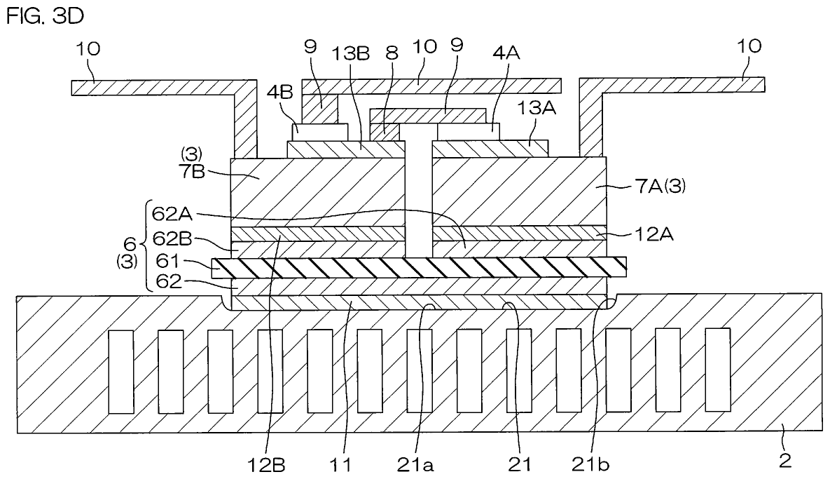

FIG. 3A to FIG. 3D are sectional views sequentially showing a manufacturing process of the semiconductor apparatus 1 shown in FIG. 1 and FIG. 2 and are sectional views corresponding to the section plane of FIG. 1.

First, as shown in FIG. 3A, an Al preformed sheet 91 for forming the first bonding structure 11 is disposed on the heat sink 2 and the insulating substrate 6 is disposed on the Al preformed sheet 91. The insulating substrate 6 is prepared from the DBC substrate and is constituted of the ceramic plate 61, the copper foil 62 that is formed on the lower surface of the ceramic plate 61, and the right and left pair of copper foils 62A and 62B that are disposed at an interval on the upper surface of the ceramic plate 61.

Also, Al preformed sheets 92A and 92B for forming the second bonding structures 12A and 12B are disposed on the pair of copper foils 62A and 62B at the upper side of the insulating substrate 6 and the metal substrates 7A and 7B are disposed on the Al preformed sheets 92A and 92B.

Also, an Al preformed sheet 93A for forming the third bonding structure 13A is disposed on the metal substrate 7A and the semiconductor chip 4A is disposed on the Al preformed sheet 93A. Further, an Al preformed sheet 93B for forming the third bonding structure 13B is disposed on the metal substrate 7B and the semiconductor chip 4B and the spacer 8 are disposed on the Al preformed sheet 93B.

Then, under a temperature environment of 150° C. to 400° C., the members disposed on the heat sink 2 are pressed at a pressure of not less than 20 MPa. Thereby, as shown in FIG. 3B, the recess portion 21 is formed in the heat sink 2 and the lower surface of the insulating substrate 6 is bonded (solid phase diffusion bonded in this preferred embodiment) to the bottom surface of the recess portion 21 via the first bonding structure 11 that includes the Al preformed sheet 91. Also, the metal substrates 7A and 7B are bonded (solid phase diffusion bonded in this preferred embodiment) to the upper surfaces of the copper foils 62A and 62B at an upper layer side of the insulating substrate 6 via the second bonding structures 12A and 12B that include the Al preformed sheets 92A and 92B. Also, the semiconductor chip 4A is bonded (solid phase diffusion bonded in this preferred embodiment) to the upper surface of the metal substrate 7A via the third bonding structure 13A that includes the Al preformed sheet 93A. Also, the semiconductor chip 4B and the spacer 8 are bonded (solid phase diffusion bonded in this preferred embodiment) to the upper surface of the metal substrate 7B via the third bonding structure 13B that includes the Al preformed sheet 93B.

Here, the bonding of the heat sink 2 and the insulating substrate 6, the bonding of the insulating substrate 6 and the metal substrates 7A and 7B, and the bonding of the metal substrate 7A and 7B and the semiconductor chips 4A and 4B and the spacer 8 may be performed separately in time.

Next, as shown in FIG. 3C, the wirings 9 are bonded to the semiconductor chips 4A and 4B and the spacer 8.

Next, as shown in FIG. 3D, the terminals 10 are bonded to the metal substrates 7A and 7B, the wirings 9, etc.

Lastly, the sealing resin 5 is formed such as to cover a portion of the terminals 10, the wirings 9, the supporting body 3, and the region of the heat sink 2 upper surface in the vicinity of the supporting body 3. The semiconductor apparatus 1 such as shown in FIG. 1 and FIG. 2 is thereby obtained.

Advantages of the present manufacturing method shall now be described. With a general manufacturing method, portions besides the heat sink (the module portion including the sealing resin 5) are manufactured and then the module portion is bonded to the heat sink. If the bonding of the module portion and the heat sink is to be performed by solid phase diffusion bonding, the heat sink and the module portion must be heated to a comparatively high temperature (approximately 300° C.) and therefore, the sealing resin 5 degrades. Thus, with the general manufacturing method, it is difficult to perform solid phase diffusion bonding of the heat sink 2 and the supporting body 3 (insulating substrate 6) under a temperature environment suited to solid phase diffusion bonding.

On the other hand, with the manufacturing method according to the preferred embodiment, since the heat sink 2 and the supporting body 3 (insulating substrate 6) are solid phase diffusion bonded before forming the sealing resin 5, heat sink 2 and the supporting body 3 (insulating substrate 6) can be solid phase diffusion bonded under a temperature environment suited to solid phase diffusion bonding. It thereby becomes possible to bond the heat sink 2 and the supporting body 3 (insulating substrate 6) firmly.

Here, heat sink 2 and the supporting body 3 (insulating substrate 6) may be silver sinter bonded instead of being solid phase diffusion bonded. Even in this case, by manufacturing the semiconductor apparatus in the same sequence as in FIG. 3A to FIG. 3D, the heat sink 2 and the supporting body 3 (insulating substrate 6) can be silver sinter bonded under a temperature environment suited to silver sinter bonding. It thereby becomes possible to bond the heat sink 2 and the supporting body 3 (insulating substrate 6) firmly.

Also, with the manufacturing method of the preferred embodiment, a portion of the sealing resin 5 can be made to infiltrate the entirety of the space portion between the portions of the first bonding structure 11 and the supporting body 3 that are disposed inside the recess portion 21 (in this preferred embodiment, substantially the entire first bonding structure 11) and the side surface 21b of the recess portion 21. The so-called anchor effect acts thereby and the sealing resin 5 is made unlikely to peel off from the heat sink 2. The bonding strength of the heat sink 2 and the supporting body 3 (insulating substrate 6) can thereby be increased. Aging degradation of the bonding interface between the supporting body 3 and the heat sink 2 can thereby be suppressed.

With the preferred embodiment described above, the insulating substrate 6 is constituted of the ceramic plate 61, the copper foil 62 that is formed on the lower surface of the ceramic plate 61, and the right and left pair of copper foils 62A and 62B that are disposed at an interval on the upper surface of the ceramic plate 61.

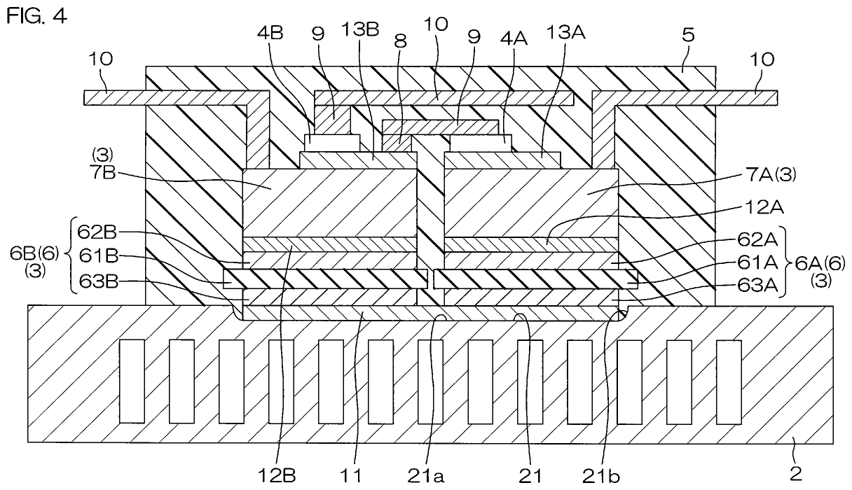

However, the insulating substrate 6 may instead be constituted from a right and left pair of insulating substrates 6A and 6B that are disposed at an interval in a right-left direction as shown in FIG. 4. One insulating substrate 6A is prepared from a DBC substrate and is constituted of a ceramic plate 61A, a copper foil 63A that is formed on a lower surface of the ceramic plate 61A, and the copper foil 62A that is formed on an upper surface of the ceramic plate 61A. The other insulating substrate 6B is prepared from a DBC substrate and is constituted of a ceramic plate 61B, a copper foil 63B that is formed on a lower surface of the ceramic plate 61B, and the copper foil 62B that is formed on an upper surface of the ceramic plate 61B. In FIG. 4, portions corresponding to respective portions in FIG. 1 are indicated with the same reference signs attached as in FIG. 1.

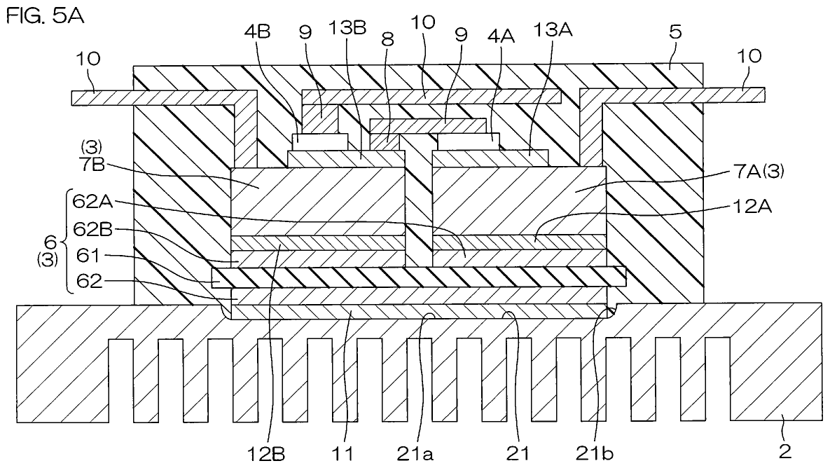

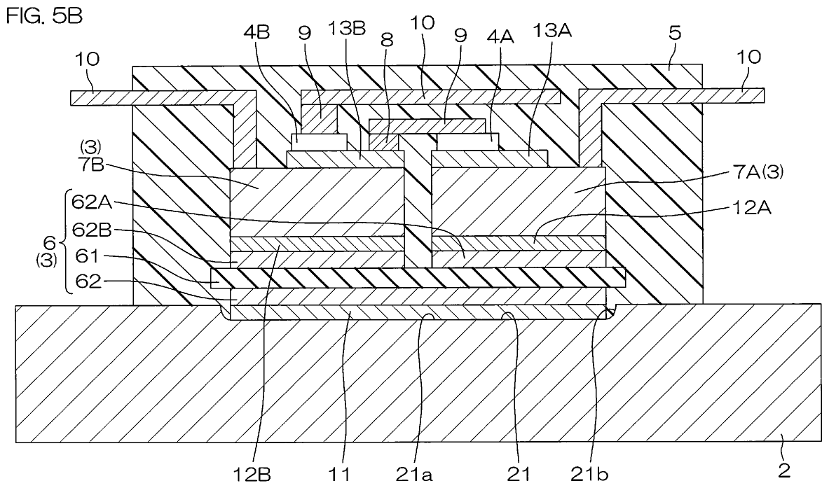

Also, with the preferred embodiment described above, the heat sink 2 is a water cooler. However, the heat sink 2 may instead be an air cooler with fins as shown in FIG. 5A. Also, the heat sink 2 may be constituted from a copper block as shown in FIG. 5B. In FIG. 5A and FIG. 5B, portions corresponding to respective portions in FIG. 1 are indicated with the same reference signs attached as in FIG. 1.

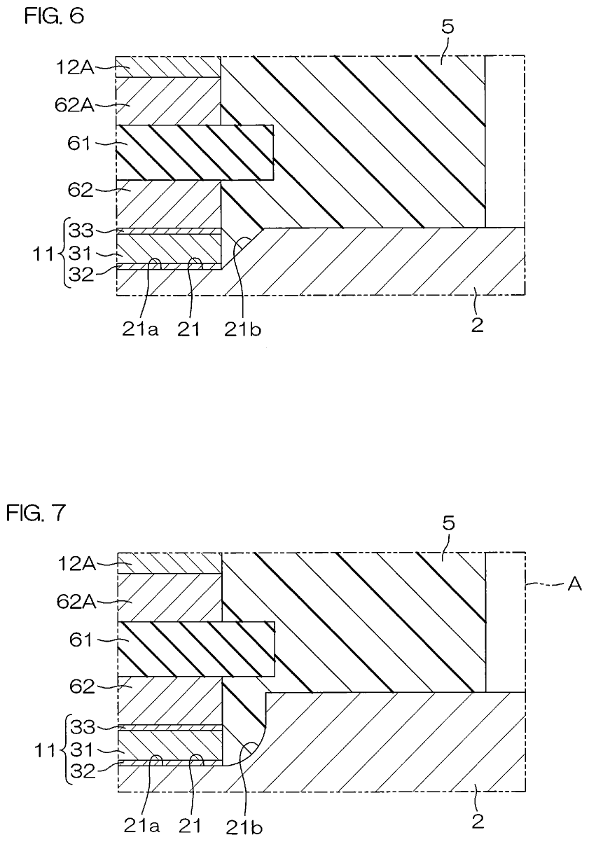

Also, with the preferred embodiment described above, the side surface 21b of the recess portion 21 is formed to the curved surface shape with which the area of the lateral cross section of the recess portion 21 increases gradually from the bottom surface of the recess portion 21 toward the opening of the recess portion 21 at the upper surface of the heat sink 2. However, as shown in FIG. 6, the side surface 21b of the recess portion 21 may instead be formed to an inclined surface shape (tapered surface shape) with which the area of the lateral cross section of the recess portion 21 increases gradually from the bottom surface of the recess portion 21 toward the opening of the recess portion 21 at the upper surface of the heat sink 2.

Here, FIG. 6 is an enlarged sectional view corresponding to FIG. 2. In FIG. 6, portions corresponding to respective portions in FIG. 2 are indicated with the same reference signs attached as in FIG. 2. Even in this modification example, a portion of the sealing resin 5 infiltrates the entirety of the space portion between the portions of the first bonding structure 11 and the supporting body 3 that are disposed inside the recess portion 21 (in the example of FIG. 6, substantially the entire first bonding structure 11) and the side surface 21b of the recess portion 21.

Also, although with the preferred embodiment described above, a depth of the recess portion 21 is substantially equal to a thickness of the first bonding structure 11, the depth of the recess portion 21 may instead be less than the thickness of the first bonding structure 11. Also, as shown in FIG. 7, the depth of the recess portion 21 may be a depth such that the entire first bonding structure 11 and a lower end portion of the supporting body 3 fit therewithin. That is, the depth of the recess portion 21 may be greater than the thickness of the first bonding structure 11.

Here, FIG. 7 is an enlarged sectional view corresponding to FIG. 2. In FIG. 7, portions corresponding to respective portions in FIG. 2 are indicated with the same reference signs attached as in FIG. 2. In this modification example, a portion of the sealing resin 5 infiltrates the entirety of the space portion between the portions of the first bonding structure 11 and the supporting body 3 that are disposed inside the recess portion 21 and the side surface 21b of the recess portion 21.

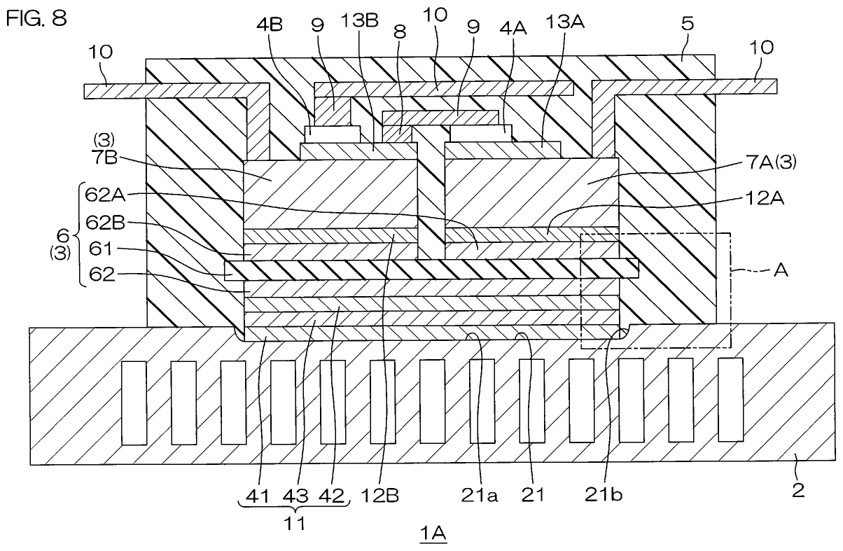

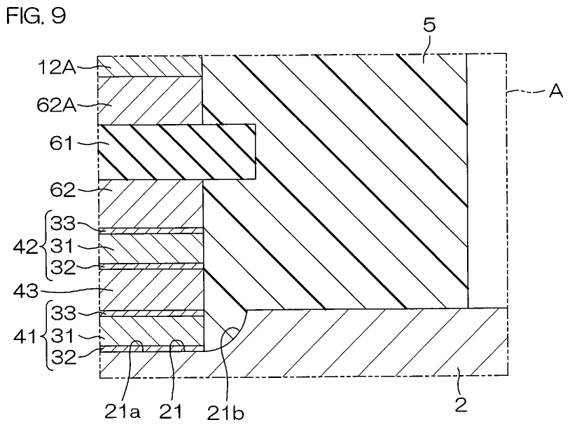

FIG. 8 is an illustrative sectional view for describing the arrangement of a semiconductor apparatus according to a second preferred embodiment of the present disclosure. FIG. 9 is an enlarged sectional view of a portion A of FIG. 8. In FIG. 8 and FIG. 9, portions corresponding to respective portions in FIG. 1 and FIG. 2 are indicated with the same reference signs attached as in FIG. 1 and FIG. 2.

With a semiconductor apparatus 1A according to the second preferred embodiment, the first bonding structure 11 is constituted from a lower bonding structure 41 that is disposed on the bottom surface 21a of the heat sink 2, an upper bonding structure 42 that is disposed above the lower bonding structure 41, and a stress buffer layer 43 interposed between the lower bonding structure 41 and the upper bonding structure 42. The lower bonding structure 41 and the upper bonding structure 42 each have the same structure as the first bonding structure 11 of the semiconductor apparatus 1 according to the first preferred embodiment. Other arrangements are the same as those of the semiconductor apparatus 1 according to the first preferred embodiment. The stress buffer layer 43 is constituted, for example, of a CuMo layer.

Even in the semiconductor apparatus 1A according to the second preferred embodiment, a portion of the sealing resin 5 infiltrates the entirety of the space portion between the portions of the first bonding structure 11 and the supporting body 3 that are disposed inside the recess portion 21 (in the example of FIG. 8 and FIG. 9, substantially the entire lower bonding structure 41) and the side surface 21b of the recess portion 21.

With the second preferred embodiment, since the first bonding structure 11 includes the stress buffer layer 43, aging degradation of the bonding interface between the supporting body 3 and the heat sink 2 can be suppressed more effectively in comparison to the first preferred embodiment.

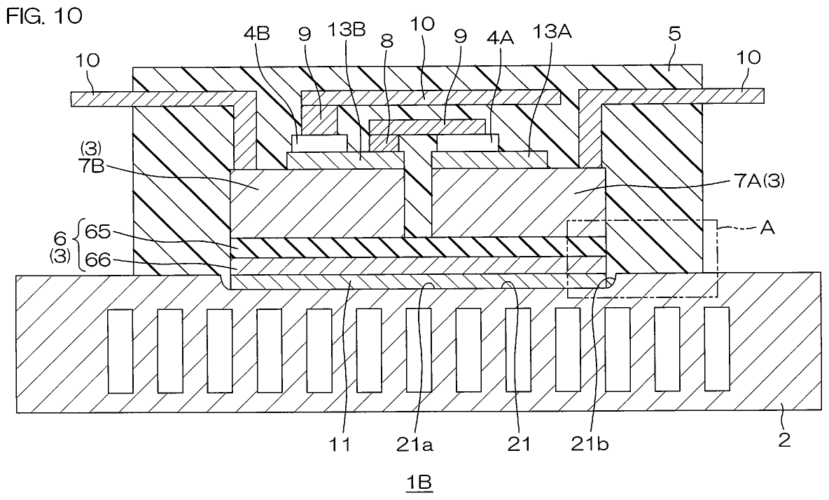

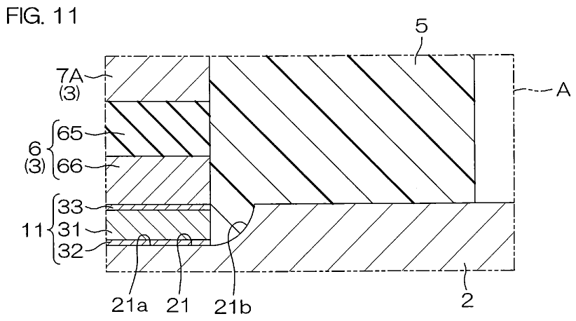

FIG. 10 is an illustrative sectional view for describing the arrangement of a semiconductor apparatus according to a third preferred embodiment of the present disclosure. FIG. 11 is an enlarged sectional view of a portion A of FIG. 10. In FIG. 10 and FIG. 11, portions corresponding to respective portions in FIG. 1 and FIG. 2 are indicated with the same reference signs attached as in FIG. 1 and FIG. 2.

With a semiconductor apparatus 1B according to the third preferred embodiment, the insulating substrate 6 is constituted from an insulating layer 65 and a metal layer (metallized layer) 66 that is formed below the insulating layer 65. The metal substrate 7A and the metal substrate 7B are disposed at an interval on the insulating layer 65. Bonding of the insulating layer 65 and the metal substrates 7A and 7B is performed not by solid phase diffusion bonding but by ceramic coating such as thermal spraying, aerosol deposition method, etc. Therefore, with the semiconductor apparatus 1B according to the third preferred embodiment, the second bonding structures 12A and 12B are not included. Other arrangements are the same as those of the semiconductor apparatus 1 according to the first preferred embodiment.

The insulating layer 65 is constituted, for example, of an Al₂O₃ layer. The insulating layer 65 may instead be an Si₃N₄ layer or an AlN layer. The metal layer 66 is constituted, for example, of a Cu layer, Ag layer, Au layer, Ni layer, Al layer, etc.

Even in the semiconductor apparatus 1B according to the third preferred embodiment, a portion of the sealing resin 5 infiltrates the entirety of the space portion between the portions of the first bonding structure 11 and the supporting body 3 that are disposed inside the recess portion 21 (in the example of FIG. 10 and FIG. 11, substantially the entire first bonding structure 11) and the side surface 21b of the recess portion 21.

Although in each of the first preferred embodiment to the third preferred embodiment described above, the first bonding structure 11 includes the solid phase diffusion bonding sheet, the first bonding structure 11 may include sintered silver or solder instead. That is, the heat sink 2 and the supporting body 3 (insulating substrate 6) may be bonded by silver sinter bonding or may be bonded by solder bonding.

Similarly, although in each of the first preferred embodiment to the third preferred embodiment described above, the third bonding structures 13A and 13B each include the solid phase diffusion bonding sheet, the third bonding structures 13A and 13B may each include sintered silver or solder instead. That is, the supporting body 3 (metal substrates 7A and 7B) and the semiconductor chips 4A and 4B may be bonded by silver sinter bonding or may be bonded by solder bonding.

Also, although in each of the first preferred embodiment and second preferred embodiment described above, the second bonding structures 12A and 12B each include the solid phase diffusion bonding sheet, the second bonding structures 12A and 12B may each include sintered silver or solder instead. That is, the insulating substrate 6 (copper foils 62A and 62B) and the metal substrates 7A and 7B may be bonded by silver sinter bonding or may be bonded by solder bonding.

In each of the first preferred embodiment to third preferred embodiment described above, the recess portion 21 is formed in the upper surface of the heat sink 2 by bonding the heat sink 2 and the supporting body 3 (insulating substrate 6) in a press-contacted state. However, the recess portion 21 may instead be formed in the upper surface of the heat sink 2 before bonding the supporting body 3 (insulating substrate 6) to the upper surface of the heat sink 2.

While preferred embodiments of the present disclosure were described in detail above, these are merely specific examples used to clarify the technical contents of the present disclosure and the present disclosure should not be interpreted as being limited to these specific examples and the scope of the present disclosure is limited only by the appended claims.

What is claimed is:

1. A semiconductor apparatus comprising:
a semiconductor chip;
a supporting body that has an upper surface and a lower surface and with which the semiconductor chip is fixed to the upper surface;
a sealing resin that is arranged to seal the semiconductor chip and the supporting body; and
a heat sink that is bonded to the lower surface of the supporting body; and
wherein a recess portion is formed in an upper surface of the heat sink,
the lower surface of the supporting body is bonded to a bottom surface of the recess portion via a bonding structure, and
the sealing resin infiltrates a gap between at least the bonding structure among the supporting body and the bonding structure and a side surface of the recess portion.

2. The semiconductor apparatus according to claim 1, wherein the side surface of the recess portion is formed to a curved surface shape or an inclined surface shape with which an area of a lateral cross section of the recess portion increases gradually from the bottom surface of the recess portion toward an opening of the recess portion at the upper surface of the heat sink.

3. The semiconductor apparatus according to claim 1, wherein the bonding structure includes a solid phase diffusion bonding sheet.

4. The semiconductor apparatus according to claim 3, wherein the solid phase diffusion bonding sheet is constituted of an Al layer, a first laminated film with which an Ni layer and an Ag layer are formed in that order on a lower surface of the Al layer, and a second laminated film with which an Ni layer and an Ag layer are formed in that order on an upper surface of the Al layer.

5. The semiconductor apparatus according to claim 1, wherein the bonding structure includes a first solid phase diffusion bonding sheet, a second solid phase diffusion bonding sheet that is disposed at an upper side of the first solid phase diffusion bonding sheet, and a stress buffer layer that is provided between the first solid phase diffusion bonding sheet and the second solid phase diffusion bonding sheet.

6. The semiconductor apparatus according to claim 5, wherein each solid phase diffusion bonding sheet is constituted of an Al layer, a first laminated film with which an Ni layer and an Ag layer are formed in that order on a lower surface of the Al layer, and a second laminated film with which an Ni layer and an Ag layer are formed in that order on an upper surface of the Al layer.

7. The semiconductor apparatus according to claim 5, wherein the stress buffer layer is constituted of a CuMo layer.

8. The semiconductor apparatus according to claim 1, wherein the bonding structure includes sintered silver.

9. The semiconductor apparatus according to claim 1, wherein the bonding structure includes solder.

10. The semiconductor apparatus according to claim 1, wherein the supporting body includes an insulating substrate and a metal substrate disposed on the insulating substrate and
the semiconductor chip is fixed to a surface of the metal substrate at an opposite side to the insulating substrate.

11. The semiconductor apparatus according to claim 1, wherein the supporting body is constituted of an insulating substrate.

12. The semiconductor apparatus according to claim 1, wherein the heat sink is a water cooler.

13. The semiconductor apparatus according to claim 1, wherein the heat sink is an air cooler.

14. The semiconductor apparatus according to claim 1, wherein the heat sink is constituted of a Cu block.

15. A method for manufacturing a semiconductor apparatus that includes a semiconductor chip, a supporting body having an upper surface and a lower surface and with which the semiconductor chip is fixed to the upper surface, a heat sink bonded to the lower surface of the supporting body, and a sealing resin sealing the semiconductor chip and the supporting body,
the method for manufacturing the semiconductor apparatus comprising:
a bonding step of bonding the semiconductor chip, the supporting body, and the heat sink; and
a sealing step of sealing the semiconductor chip and the supporting body by the sealing resin.

16. The method for manufacturing a semiconductor apparatus according to claim 15, wherein in the bonding step, at least bonding of the supporting body and the heat sink among bonding of the semiconductor chip and the supporting body and the bonding of the supporting body and the heat sink is performed by solid phase diffusion bonding.
